(19) United States
(12) Patent Application Publication
(10) Pub. No.: US 2024/0096844 A1
(43) Pub. Date: Mar. 21, 2024

(54) BONDED CONNECTION MEANS

(71) Applicant: Siemens Aktiengesellschaft, 80333 München (DE)

(72) Inventors: PHILIPP KNEISSL, Nürnberg (DE); FELIX ZEYSS, Erlangen (DE); MARKUS PFEIFER, Nürnberg (DE)

(73) Assignee: Siemens Aktiengesellschaft, 80333 München (DE)

(21) Appl. No.: 18/265,578

(22) PCT Filed: Oct. 13, 2021
(86) PCT No.: PCT/EP2021/078279

§ 371 Date: Jun. 6, 2023

(30) Foreign Application Priority Data
Dec. 7, 2020 (EP) 20212258.6

(51) Int. Cl. H01L 23/00; H01L 23/34; H01L 25/16

(52) U.S. Cl. CPC H01L 24/45; H01L 23/34; H01L 24/48; H01L 25/16; H01L 2224/45015; H01L 2224/4556; H01L 2224/45565; H01L 2224/48227; H01L 2924/13055; H01L 2924/13091

(57) ABSTRACT

A semiconductor module includes a semiconductor element, a substrate, and a bond connector designed as a gate resistor, shunt, resistor in an RC filter or fuse. The bond connector includes a core made of a first metal material and a jacket which is designed to envelope the core and made from a second metal material that is different from the first metal material, with the first metal material having an electrical conductivity which is lower than an electrical conductivity of the second metal material. At least one of the semiconductor element and the substrate is connected to the bond connector.

Further, the invention relates to a semiconductor module having at least one semiconductor element, a substrate and at least one bonding connection means.

Furthermore, the invention relates to a power converter having at least one semiconductor module.

Moreover, the invention relates to the use of at least one bonding connection means as a gate resistor, shunt, resistor In an RC filter, or fuse in a semiconductor module.

In addition, the invention relates to the use of at least one bonding connection means for the purpose of measuring current or determining temperature in a semiconductor module.

In power converters of this kind, bonding connection means, which take the form for example of bonding wires or bonding ribbons, are typically used only to connect a semiconductor element to a substrate in a semiconductor module. The term “power converter” should be understood to mean for example a rectifier, power inverter, frequency converter or DC-to-DC converter. For this reason, in the case of such bonding connection means, the focus is typically on the reduction of parasitic resistance and parasitic inductance.

The patent specification DE 10 2010 031 993 B4 describes a method for manufacturing a bonding wire having a wire core made from a first material and a wire jacket that envelops the wire core and is made from a second material, wherein the first material has a first metal and the second material has a second metal, and the first metal and the second metal are different.

The patent specification EP 2 662 891 B1 describes a method for manufacturing an aluminum-coated copper bonding wire.

The published application EP 2 662 891 61 describes a semiconductor device having external wiring. The external wiring may be a wire that is electrically connected to an emitter of the transistor portion. The clad wire has a core material and an external peripheral portion surrounding the core material. The core material may be formed from iron or an iron alloy, and the external peripheral portion may be formed from aluminum or an aluminum alloy.

The published application US 2003/0081652 A1 describes a composite wire, in particular a connection wire for electrical temperature sensors, which has a jacket having platinum and enveloping a core made from an alloy, wherein the core is made from a nickel-based alloy which self-passivates at the core surface, and wherein the nickel-based alloy contains chromium in the range of 16 to 22 weight %.

The published application JP H 0332033 A describes a composite conductor comprising a core material, which is not plastically deformed with energy used in the connection, and an outer surface element, which covers the core material and is plastically deformed.

Defined resistors that are needed in a semiconductor module, which are needed for example for controlling a semiconductor element or for detecting a current value, so-called shunt resistors, take the form for example of external resistors, which take up additional installation space. As an alternative, for example, shunt resistors take the form of internal components that are integrated into the semiconductor element, in which case such internal components in particular have low current-carrying capacity and high levels of temperature drift, and entail high costs in terms of installation space on the chip.

In this context, it is an object of the present invention to provide a bonding connection means, for the purpose of connecting a semiconductor element to a substrate, that enables optimization of the layout.

According to the invention, the object is achieved by a semiconductor module having at least one semiconductor element, a substrate and at least one such bonding connection means, wherein the semiconductor element and/or the substrate are connected to the at least one bonding connection means, wherein the at least one bonding connection means has a core and a jacket that envelops the core, in particular entirely envelops it, wherein the core (4) is manufactured from a first metal material and the jacket is manufactured from a second metal material that is different from the first metal material, and wherein the first metal material of the core has a lower electrical conductivity than the second metal material of the jacket, wherein at least one bonding connection means is configured as a gate resistor, shunt, resistor in an RC filter or fuse.

Furthermore, according to the invention the object is achieved by a power converter having at least one semiconductor module.

Moreover, according to the invention the object is achieved by the use of at least one bonding connection means as a gate resistor, shunt, resistor in an RC filter or fuse in a semiconductor module, wherein the at least one bonding connection means has a core and a jacket that envelops the core, in particular entirely envelops it, wherein the core is manufactured from a first metal material and the jacket is manufactured from a second metal material that is different from the first metal material, and wherein the first metal material of the core has a lower electrical conductivity than the second metal material of the jacket.

In addition, according to the invention the object is achieved by the use of at least one bonding connection means for the purpose of measuring current or determining temperature in a semiconductor module, wherein the at least one bonding connection means has a core and a jacket that envelops the core, in particular entirely envelops it, wherein the core is manufactured from a first metal material and the jacket is manufactured from a second metal material that is different from the first metal material, and wherein the first metal material of the core has a lower electrical conductivity than the second metal material of the jacket.

The advantages and preferred embodiments that are given below with reference to the bonding connection means may be applied to the semiconductor module, the power converter and the uses where this is meaningful.

The object underdying the invention is to optimize a layout of a semiconductor module, in that an existing bonding connection means is used as a resistor and replaces for example an external resistor, consequently saving on installation space. A bonding connection means of this kind takes the form for example of a bonding wire or bonding ribbon and has a core and a jacket that envelops the core, in particular entirely envelops it, wherein the core is manufactured from a first metal material and the jacket is manufactured from a second metal material that is different from the first metal material. The second metal material of the jacket, also designated the jacket material or base material, is in particular suitable for connection to a surface, such as the substrate and/or the semiconductor element, by ultrasonic welding, for example by ultrasonic friction welding. For example, the jacket material contains aluminum, copper or gold. The first metal material of the core has a lower electrical conductivity than the second metal material of the jacket. In particular, the first metal material of the core contains a resistance alloy, making it possible to create a large resistance with a short length of bonding wire, as a result of which for example parasitic inductance is reduced. By replacing a discrete external component such as a gate resistor, a shunt resistor or a resistor In an RC filter by such bonding connection means, in particular already existing bonding connection means, there is a saving on installation space and it becomes possible to optimize the layout. Further, no additional processing step is required. In particular, as a result of saving on space, replacing a discrete shunt resistor by, for example, bonding connection means connected in parallel makes individual current measurements for parallel semiconductor elements possible. An additional saving on space is achieved for example in that the bonding connection means that take the form of a shunt resistor span other conductors that are in particular mounted on the substrate in structured form. This additionally enables even greater freedom in optimization of the layout. Further, the use of a bonding connection means of this kind makes it possible to measure current or determine temperature. Current is measured for example by measuring a drop in voltage across a bonding connection means through which current is flowing, wherein the known resistance of the bonding connection means makes it possible to determine the current through the bonding connection means. Temperature is determined for example by measuring the drop in voltage across a bonding connection means through which a defined current is flowing, and a temperature is determined from this by means of a material-specific conversion factor.

A further embodiment provides for the electrical conductivity of the first metal material to be at most 10%, in particular at most 5%, of the electrical conductivity of the second metal material. This is advantageous because a resistance of the bonding connection means is variable over a broad range in a defined manner.

A further embodiment provides for the first metal material of the core to have a conductivity in the range of from 0.5 MS/m to 20 MS/m, in particular in the range of from 0.5 MS/m to 4 MS/m. With conductivities of this kind, it is possible to produce comparatively high defined resistances using short bonding wires.

A further embodiment provides for the resistance of the first metal material of the core to have a temperature coefficient of ±0.1-10⁻³/K⁻¹ in the range of from −40° C. to 200° C. A temperature coefficient that is flat in this way makes it possible to produce a defined resistance over a large temperature range.

A further embodiment provides for the core to contain Zeranin, Manganin, Constantan or Isaohm. Because of their flat temperature coefficient, resistance alloys of this kind make it possible to produce a defined resistance over a large temperature range.

A further embodiment provides for the core to contain a PTC thermistor. In particular, the core is manufactured from platinum. Bonding connection means having a core of this kind are suitable for measuring temperature.

A further embodiment provides for the first metal material of the core to have a resistance with a substantially linear temperature profile. A linear temperature profile of the resistance is present in particular if a second and/or third-order temperature coefficient is at least 100 times, in particular 500 times, smaller than a first-order temperature coefficient. For example, the core is manufactured from Resistherm (NiFe30). A core taking such a form makes it possible to manufacture a bonding connection means of which the resistance is adjustable and defined by the length and/or cross-sectional geometry, wherein the resistance is dependent on the temperature of the bonding connection means.

A further embodiment provides for a surface area of the core to represent, in terms of proportion, at least 90% of the cross-sectional surface area of the bonding connection means. This is advantageous because a resistance of the bonding connection means is variable over a broad range in a defined manner.

The invention is described and explained in more detail below with reference to the exemplary embodiments illustrated in the figures.

In the figures:

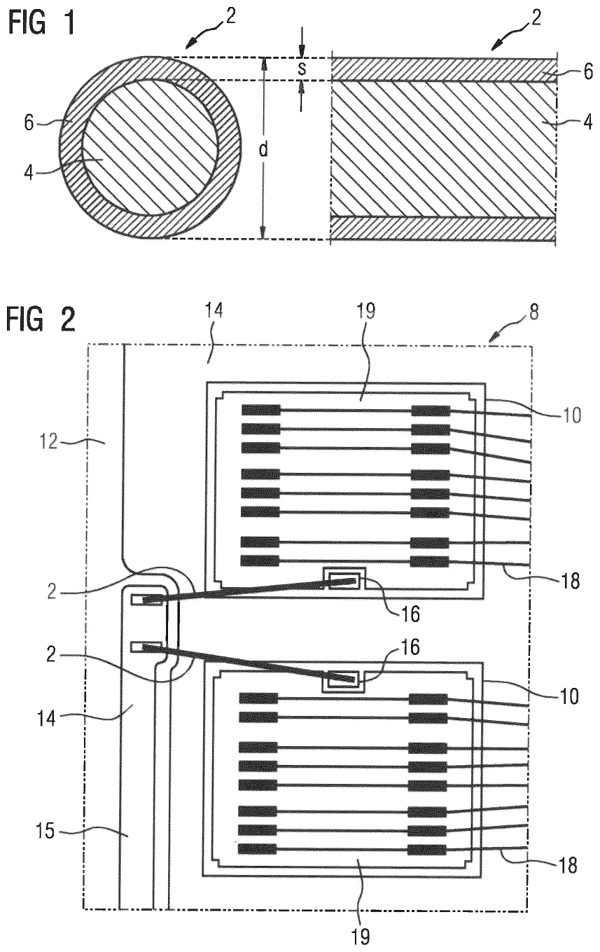

FIG. 1 shows a schematic illustration of a first embodiment of a bonding connection means,

FIG. 2 shows a schematic illustration of a semiconductor module that has parallel semiconductor elements and bonding connection means taking the form of gate resistors,

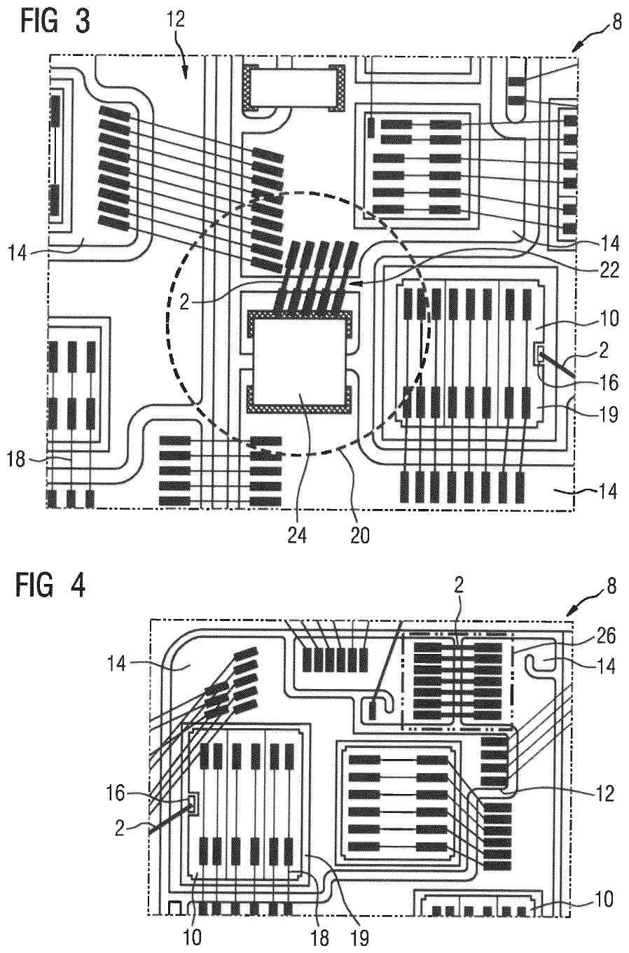

FIG. 3 shows a schematic illustration of a semiconductor module having an RC filter,

FIG. 4 shows a schematic illustration of a semiconductor module having bonding connection means that take the form of a shunt resistor,

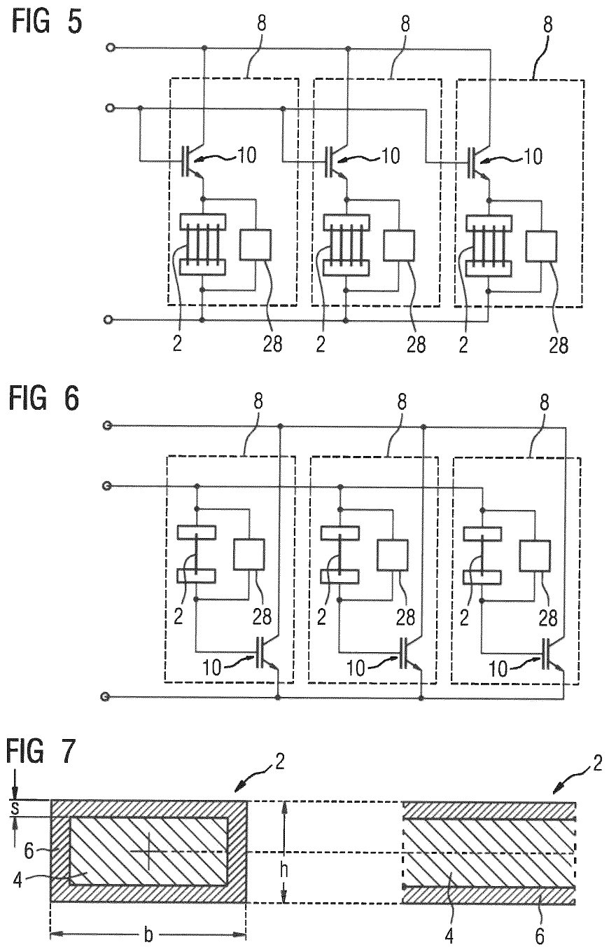

FIG. 5 shows a schematic illustration of parallel semiconductor elements having bonding connection means in the load current path,

FIG. 6 shows a schematic illustration of parallel semiconductor elements having bonding connection means in the gate path, and

FIG. 7 shows a schematic illustration of a second embodiment of a bonding connection means.

The exemplary embodiments explained below are preferred embodiments of the invention. In the exemplary embodiments, the described components of the embodiments each present individual features of the invention, to be considered separately from one another, which also each develop the invention independently of one another, and hence are also to be regarded as a constituent part of the invention individually or in a different combination from that shown. Furthermore, the described embodiments may also be supplemented by further features of the invention which have already been described.

Like reference characters have the same meaning in the different figures.

FIG. 1 shows a schematic illustration of a first embodiment of a bonding connection means 2, which by way of example takes the form of a bonding wire with a circular cross section. While a cross section of the bonding wire is illustrated on the left, a longitudinal section of the bonding wire is represented on the right. The bonding wire has a core 4 and a jacket 6 that entirely envelops the core 4, wherein the core 4 is manufactured from a first metal material and the jacket 6 is manufactured from a second metal material that is different from the first metal material. A surface area of the core 4 represents, in terms of proportion, at least 90% of the cross-sectional surface area of the bonding wire, wherein a diameter d of the bonding wire is in the range of from 125 μm to 500 μm. A thickness s of the jacket is at most 15 μm.

The second metal material, which is also designated the jacket material or base material, is configured to make an electrical conductive connection between a semiconductor element and a surface, in particular a substrate. A bonding connection of this kind is made for example by ultrasonic welding, in particular by ultrasonic friction welding, wherein the jacket material contains for example aluminum, copper or gold. The first metal material of the core 4 has a lower electrical conductivity than the jacket material, wherein the electrical conductivity of the first metal material is at most 10%, in particular at most 5%, of the electrical conductivity of the jacket material. In particular, the first metal material of the core 4 has a defined resistance, wherein the conductivity of the first metal material lies in the range of from 0.5 MS/m to 20 MS/m, in particular in the range of from 0.5 MS/m to 4 MS/m. The bonding wire in FIG. 1 may be manufactured for example by wire drawing.

FIG. 2 shows a schematic illustration of a semiconductor module 8, which has parallel semiconductor elements 10 and bonding connection means 2 that take the form of gate resistors and connect the parallel semiconductor elements 10 to a substrate 12. In particular, the bonding connection means 2 that take the form of gate resistors are connected to a structured metallized part 14 of the substrate 12. For example, each of the semiconductor elements 10 takes the form of a transistor, in particular an insulated-gate bipolar transistor (IGBT), a metal-oxide semiconductor field-effect transistor (MOSFET) or a field-effect transistor. A common supply line 15 is connected by way of a respective bonding connection means 2 to a gate contact 16 of the respective semiconductor element 10. Further bonding wires 18 are provided for the purpose of making further contact, in particular of emitter contacts 19, between the semiconductor elements 10 and the substrate 12.

In order to achieve a constant resistance over a defined temperature range, the core 4 of the bonding connection means 2 is manufactured from a resistance alloy. For example, the resistance of the first metal material of the core 4 has a temperature coefficient of ±0.1·10⁻³/K⁻¹ in the range of from −40° C. to 200° C. The resistance alloy contains for example Zeranin, Manganin, Constantan or Isaohm. The gate resistors that are formed by the bonding connection means 2 may be adapted individually, for example by the length and/or cross-sectional geometry of the bonding connection means 2, in particular for parallel semiconductor elements 10.

As an alternative, the core 4 of the bonding connection means 2 is manufactured from a material having a high, in particular a defined, temperature coefficient. A high temperature coefficient of this kind lies in the range of from 3·10⁻³/K⁻¹ to 10·10⁻³/K⁻¹ at 20° C. In particular, the first metal material of the core 4 has a resistance with a substantially linear temperature profile. For example, the core 4 contains a PTC thermistor such as platinum or Resistherm (NiFe30). A core 4 taking such a form makes it possible to manufacture a bonding connection means 2 of which the resistance is adjustable and defined by the length and/or cross-sectional geometry, wherein the resistance is dependent on the temperature of the bonding connection means 2. When the semiconductor element 10 is heated the bonding connection means 2 taking the form of a gate resistor is also heated, and resistance of the bonding connection means 2 increases with increasing temperature, and so switching of the semiconductor element 10 takes place more slowly as a result of current feedback and there is a reduction in the load current. For this reason, using bonding connection means 2 that have a core 4 made from a material with a high temperature coefficient as gate resistors makes it possible to balance the load currents. Otherwise, the form taken by the bonding connection means 2 in FIG. 2 corresponds to that in FIG. 1.

FIG. 3 shows a schematic illustration of a semiconductor module 8 having an RC filter 20, wherein a resistor 22 of the RC filter 20 is configured by, in particular, five parallel bonding connection means 2, while a capacitor 24 of the RC filter 20 takes the form of a snubber capacitor. Otherwise, the form taken by the semiconductor module 8 and the bonding connection means 2 in FIG. 3 corresponds to that in FIG. 2.

FIG. 4 shows a schematic illustration of a semiconductor module 8 having bonding connection means 2 that take the form of a shunt resistor 26. A shunt resistor 26 of this kind has the effect of saving on installation space, with the result that it becomes possible to take individual current measurements for parallel semiconductor elements 10 in a manner saving on space. If the core 4 of the bonding connection means 2 is manufactured from a material having a high, in particular a defined, temperature coefficient, as described in FIG. 2. For example, the core 4 contains a PTC thermistor such as platinum or Resistherm (NiFe30). Heating of the bonding connection means 2 in a manner dependent on load current results in negative feedback: the greater a load current flowing through the bonding connection means 2 of the shunt resistor 26, the higher its temperature. Because the resistance of the bonding connection means 2 increases with temperature, the load current is limited. When semiconductor elements 10 are connected in parallel, it is possible to optimize balanced distribution of the load current if the shunt resistor 26 that is formed in this manner is connected in series with the respective semiconductor elements 10. A thermal coupling between the shunt resistor 26 and the respective semiconductor element 10, for example by direct bonding of the semiconductor element 10 to the bonding connection means 2 of the shunt resistor 26, amplifies the feedback. Otherwise, the form taken by the semiconductor module 8 and the bonding connection means 2 in FIG. 4 corresponds to that in FIG. 2.

FIG. 5 shows a schematic illustration of parallel semiconductor elements 10 having bonding connection means 2 in the load current path, wherein the parallel semiconductors are arranged on parallel semiconductor modules 8. As described in FIG. 2, the core 4 of the bonding connection means 2 is manufactured from a material having a high, in particular a defined, temperature coefficient. For example, the core 4 contains a PTC thermistor such as platinum or Resistherm (NiFe30). In this way, a respective temperature-dependent resistance is formed by the bonding connection means 2 in the load current paths of the parallel semiconductor modules 8, and this results in balancing across the semiconductor modules 8. If the load current is known, it is possible for measuring devices 28 to determine temperature. With the load current known, temperature is determined in particular by measuring the drop in voltage at the bonding connection means 2 and determining the temperature from this by means of a material-specific conversion factor. Optionally, the bonding connection means 2 take the form of a fuse which, if there is a high overcurrent, undergoes pronounced heating and becomes very high in resistance or burns out. Otherwise, the form taken by the semiconductor modules 8 and the bonding connection means 2 in FIG. 5 corresponds to that in FIG. 2.

FIG. 6 shows a schematic illustration of parallel semiconductor elements 10 having bonding connection means 2 in the gate path. By analogy with FIG. 5, formed in the gate paths of the parallel semiconductor modules 8 by the bonding connection means 2 is a respective temperature-dependent resistance, and this results in balancing across the semiconductor modules 8. If the gate current is known, it is possible for measuring devices 28 to determine temperature, as described in FIG. 5. Otherwise, the form taken by the semiconductor modules 8 and the bonding connection means 2 in FIG. 6 corresponds to that in FIG. 5.

FIG. 7 shows a schematic illustration of a second embodiment of a bonding connection means 2, which by way of example takes the form of a bonding ribbon of rectangular cross section. While a cross section of the bonding ribbon is illustrated on the left, a longitudinal section of the bonding ribbon is represented on the right. By analogy with FIG. 1, the bonding ribbon has a core 4 and a jacket 6 that entirely envelops the core 4, wherein the core 4 is manufactured from a first metal material and the jacket 6 is manufactured from a second metal material that is different from the first metal material. As an alternative, the jacket 6 of the bonding ribbon does not entirely envelop the core 4. For example, the jacket 6 of the bonding ribbon is connected to the core 4 on opposite long sides of the rectangular cross section, in the manner of a sandwich. In this configuration, the short side faces of the bonding ribbon do not have any function in the bonding process. A surface area of the core 4 represents, in terms of proportion, at least 90% of the cross-sectional surface area of the bonding ribbon, wherein the bonding ribbon has for example a width b of 4 mm and a height h of 1 mm.

To summarize, the invention relates to a bonding connection means 2 for connecting a semiconductor element 10 to a substrate 12. In order to enable optimization of the layout, it is proposed that the bonding connection means 2 should have a core 4 and a jacket 6 that envelops the core 4, in particular entirely envelops it, wherein the core 4 is manufactured from a first metal material and the jacket 6 is manufactured from a second metal material that is different from the first metal material, and wherein the first metal material of the core 4 has a lower electrical conductivity than the second metal material of the jacket 6.

What is claimed is:

1.-13. (canceled)

14. A semiconductor module, comprising:
a semiconductor element;
a substrate; and
a bond connector designed as a gate resistor, shunt, resistor in an RC filter or fuse, said bond connector including a core made of a first metal material and a jacket which is designed to envelope the core and made from a second metal material that is different from the first metal material, with the first metal material having an electrical conductivity which is lower than an electrical conductivity of the second metal material,
wherein at least one of the semiconductor element and the substrate is connected to the bond connector.

15. The semiconductor module of claim 14, wherein the jacket is designed to entirely envelop the core.

16. The semiconductor module of claim 14, wherein the electrical conductivity of the first metal material is at most 10% of the electrical conductivity of the second metal material.

17. The semiconductor module of claim 14, wherein the electrical conductivity of the first metal material is at most 5% of the electrical conductivity of the second metal material.

18. The semiconductor module of claim 14, wherein the electrical conductivity of the first metal material in a range of from 0.5 MS/m to 20 MS/m.

19. The semiconductor module of claim 14, wherein the electrical conductivity of the first metal material is in a range of from 0.5 MS/m to 4 MS/m.

20. The semiconductor module of claim 14, wherein the first metal material has a resistance having a temperature coefficient of ±0.1·10⁻³/K⁻¹ in a range of from −40° C. to 200° C.

21. The semiconductor module of claim 14, wherein the core contains Zeranin, Manganin, Constantan or Isaohm.

22. The semiconductor module of claim 14, wherein the core includes a PTC thermistor.

23. The semiconductor module of claim 14, wherein the first metal material has a resistance with a substantially linear temperature profile.

24. The semiconductor module of claim 14, wherein a surface area of the core represents, in terms of proportion, at least 90% of a cross-sectional surface area of the bonding connector.

25. The semiconductor module of claim 14, wherein the bonding connector is structured to measure a current.

26. The semiconductor module of claim 14, the bonding connector is structured to determine a temperature.

27. A power converter, comprising a semiconductor module as set forth in claim 14.

28. A bonding connector for use as a gate resistor, shunt, resistor in an RC filter or fuse in a semiconductor module, said bonding connector comprising:
a core made of a first metal material; and
a jacket which is designed to envelope the core and made from a second metal material that is different from the first metal material, with the first metal material having an electrical conductivity which is lower than an electrical conductivity of the second metal material.

29. The bonding connector of claim 28, wherein the jacket is designed to entirely envelop the core.

30. A bonding connector for measuring current or determining temperature in a semiconductor module, said bonding connector comprising:
a core made of a first metal material; and
a jacket which is designed to envelope the core and made from a second metal material that is different from the first metal material, with the first metal material having an electrical conductivity which is lower than an electrical conductivity of the second metal material.

31. The bonding connector of claim 30, wherein the jacket is designed to entirely envelop the core.
